(19) United States
(12) Patent Application Publication
(10) Pub. No.: US 2025/0216434 A1
(43) Pub. Date: Jul. 3, 2025

(54) NOISE MODEL GENERATING METHOD AND NOISE MODEL GENERATING DEVICE

(71) Applicants: Kabushiki Kaisha Toshiba, Tokyo (JP); Toshiba Electronic Devices & Storage Corporation, Tokyo (JP)

(72) Inventors: Hidetoshi MIYAHARA, Kawasaki Kanagawa (JP); Yuusuke IMAIZUMI, Kawasaki Kanagawa (JP); Atsushi TOMISHIMA, Matsudo Chiba (JP)

(21) Appl. No.: 18/827,667

(22) Filed: Sep. 6, 2024

(30) Foreign Application Priority Data
Dec. 27, 2023 (JP) 2023-220710

(51) Int. Cl. G01R 29/26; G01R 31/317

(52) U.S. Cl. CPC G01R 29/26; G01R 31/31708

(57) ABSTRACT

A noise model generating method includes calculating a transfer function from inside of an integrated circuit of an electric circuit to a measurement point in the electric circuit; acquiring a noise level waveform of a frequency with a high correlation with a trigger signal from measurement results of noise when the integrated circuit is caused to output the trigger signal; and generating the noise model of the integrated circuit on the basis of the transfer function calculated and the noise level waveform acquired. Acquiring the noise level waveform further includes: causing the integrated circuit to output a trigger signal; measuring the trigger signal and noise at the measurement point at time intervals to obtain measured values at the measurement point and at the time intervals; performing a conversion operation to generate, for each frequency, the noise level waveform indicating a change of the noise over time on the basis of the measured values at the measurement point; calculating, for each frequency, a correlation value indicating a correlation between the noise level waveform and a change of the trigger signal over time; and performing a filtering operation to extract the noise level waveform of a frequency with a high correlation from the correlation value.

### CROSS-REFERENCE TO RELATED APPLICATION

This application is based upon and claims the benefit of priority from Japanese Patent Application No. 2023-220710, filed on Dec. 27, 2023; the entire contents of which are incorporated herein by reference.

### FIELD

Embodiments described herein relate generally to a noise model generating method and a noise model generating device.

### BACKGROUND

Noise generated in integrated circuits will in some cases cause magnetic disturbance in some devices other than the integrated circuit and also will affect on circuit operations thereof. Various noise model generating methods have been proposed for the purpose of control of noise in integrated circuits, as disclosed in Japanese Unexamined Patent Application, First Publication No. 2009-541891. Recently, there has been demand for generating some noise model with higher accuracy.

### BRIEF DESCRIPTION OF THE DRAWINGS

FIG. 1 is a schematic diagram of a noise model generating device according to an embodiment.

FIG. 2 is a block diagram illustrating a noise model generating method according to the embodiment.

FIG. 3 is a diagram illustrating an example of a transfer function H(f) that is calculated in a transfer function calculating operation.

FIG. 4 is a graph illustrating changes over time of a trigger signal voltage and a noise voltage that are measured in a measurement operation.

FIG. 5 is a graph illustrating a noise level waveform that is generated in a conversion operation.

FIG. 6 is a graph illustrating a noise level waveform at a first frequency F1 in FIG. 5.

FIG. 7 is a graph illustrating a noise level waveform at a second frequency F2 in FIG. 5.

FIG. 8 is a graph illustrating a noise level waveform at a third frequency F3 in FIG. 5.

FIG. 9 is a graph illustrating a correlation value Cn(f) between a noise level waveform and a trigger signal according to the embodiment that is acquired in a correlation value calculating operation.

FIG. 10 is a diagram illustrating characteristics of a band-pass filter B(f) according to the embodiment.

FIG. 11 is a diagram illustrating an extracted noise level waveform Vnn(f, t) according to the embodiment.

### DETAILED DESCRIPTION

In some embodiments, a noise model generating method may include, but is not limited to, calculating a transfer function from inside of an integrated circuit of an electric circuit to a measurement point in the electric circuit; acquiring a noise level waveform of a frequency with a high correlation with a trigger signal from measurement results of noise when the integrated circuit is caused to output the trigger signal; and generating the noise model of the integrated circuit on the basis of the transfer function calculated and the noise level waveform acquired. Acquiring the noise level waveform may further include, but is not limited to: causing the integrated circuit to output a trigger signal; measuring the trigger signal and noise at the measurement point at time intervals to obtain measured values at the measurement point and at the time intervals; performing a conversion operation to generate, for each frequency, the noise level waveform indicating a change of the noise over time on the basis of the measured values at the measurement point; calculating, for each frequency, a correlation value indicating a correlation between the noise level waveform and a change of the trigger signal over time; and performing a filtering operation to extract the noise level waveform of a frequency with a high correlation from the correlation value.

In some embodiments, a noise model generating system may include, but is not limited to, a computer configured to perform a noise model generating method. The noise model generating method may include, but is not limited to, calculating a transfer function from inside of an integrated circuit of an electric circuit to a measurement point in the electric circuit; acquiring a noise level waveform of a frequency with a high correlation with a trigger signal from measurement results of noise when the integrated circuit is caused to output the trigger signal; and generating the noise model of the integrated circuit on the basis of the transfer function calculated and the noise level waveform acquired. Acquiring the noise level waveform further may include, but is not limited to, causing the integrated circuit to output a trigger signal; measuring the trigger signal and noise at the measurement point at time intervals to obtain measured values at the measurement point and at the time intervals; performing a conversion operation to generate, for each frequency, the noise level waveform indicating a change of the noise over time on the basis of the measured values at the measurement point; calculating, for each frequency, a correlation value indicating a correlation between the noise level waveform and a change of the trigger signal over time; and performing a filtering operation to extract the noise level waveform of a frequency with a high correlation from the correlation value.

Hereinafter, a noise model generating method and a noise model generating device according to an embodiment will be described with reference to the accompanying drawings.

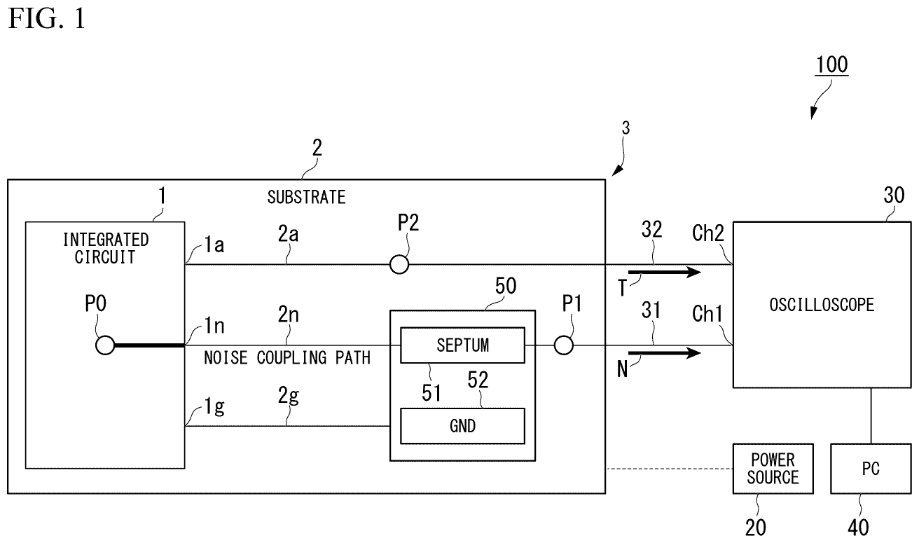

FIG. 1 is a schematic diagram of a noise model generating device 100 according to an embodiment (hereinafter simply referred to as a generation device). The generation device 100 includes a power source 20, an oscilloscope 30, a computer 40, and a strip line 50. An electric circuit 3 including an integrated circuit 1 of which a noise model is to be calculated is connected to the generation device 100.

The power source 20 is connected to a power supply line (not illustrated) of the electric circuit 3 and supplies electric power to the electric circuit 3. The power source 20 is connected to the computer 40 and is controlled by the computer 40. The oscilloscope 30 is connected to a noise measuring point (measurement point) P1 and an output measuring point P2 provided in the electric circuit 3 and measures noise N and a trigger signal T of the electric circuit 3. The computer 40 is connected to the oscilloscope 30 to control the oscilloscope 30 and calculates a noise model at an observation point P0 in the integrated circuit on the basis of an output result from the oscilloscope 30.

The electric circuit 3 in this embodiment includes an integrated circuit 1 and a substrate 2 on which the integrated circuit 1 is mounted. The integrated circuit 1 includes a plurality of terminals connected to the substrate 2. The terminals of the integrated circuit 1 include a measurement terminal 1ₙ which is a noise measurement target, an output terminal 1a that outputs a trigger signal, and a ground terminal 1g that is connected to a ground pattern 2g of the substrate 2. The measurement terminal 1ₙ which is a terminal of the integrated circuit 1 is connected to the observation point P0 in the integrated circuit.

A plurality of circuit patterns are formed on the substrate 2. The circuit patterns include a ground pattern 2g, an output pattern 2a to which the output terminal 1a is connected, and a noise coupling path 2n to which the measurement terminal 1ₙ is connected. When radiation noise propagating in a space is measured instead of conductive noise propagating in a conductor, a noise propagation path from the observation point P0 rather than from the top of the substrate 2, may be used instead of the noise coupling path 2n.

A noise measuring point P1 for measuring noise N of the integrated circuit 1 and an output measuring point P2 for measuring a trigger signal T are provided in the electric circuit 3. One end of a noise measuring line 31 is connected to the noise measuring point P1. The other end of the noise measuring line 31 is connected to a noise measuring channel Ch1 of the oscilloscope 30. One end of an output measuring line 32 is connected to the output measuring point P2. The other end of the output measuring line 32 is connected to a trigger signal measuring channel Ch2 of the oscilloscope 30.

In this embodiment, the noise measuring point P1 is provided on the noise coupling path 2n. That is, the noise measuring line 31 extending from the oscilloscope 30 is connected to the noise coupling path 2n. In this embodiment, a strip line 50 is provided in the middle of the noise coupling path 2n. The ground pattern 2g on the substrate 2 is connected to a housing ground 52 of the strip line 50. Noise from the noise coupling path 2n is received by a septum 51 in the strip line 50 and is output as noise N to the noise measuring line 31.

The strip line 50 may not be provided in the middle of the noise coupling path 2n. The noise measuring point P1 may be provided on another circuit pattern on the substrate 2. For example, the noise measuring point P1 may be provided on the output pattern 2a. In this case, it is preferable to input only noise N obtained by filtering a trigger signal output from the output pattern 2a to the trigger signal measuring channel Ch2 of the oscilloscope 30.

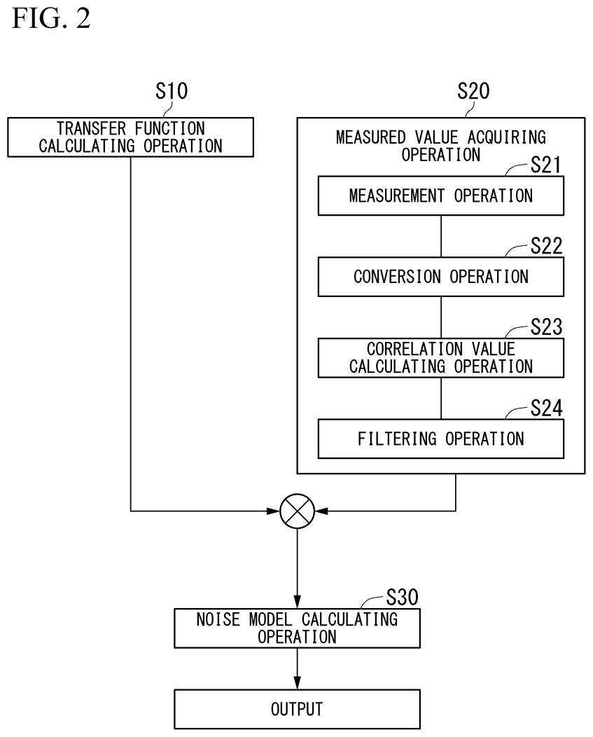

The output measuring point P2 in this embodiment is provided on the output pattern 2a. However, the arrangement of the output measuring point P2 is not limited to this embodiment, and the output measuring point P2 may be provided at any position on the electric circuit 3 as long as it can output a trigger signal T of the integrated circuit 1. FIG. 2 is a block diagram illustrating a noise model generating method according to this embodiment.

As illustrated in FIG. 2, the noise model generating method according to this embodiment includes a transfer function calculating operation S10, a noise level waveform acquiring operation S20, and a noise model generating operation S30.

The transfer function calculating operation S10 is an operation of calculating a transfer function H(f) from the observation point P0 in the integrated circuit 1 to the noise measuring point P1 on the electric circuit 3. The transfer function is represented as an impedance of the electric circuit 3. In this embodiment, the transfer function calculating operation S10 is performed by the computer 40. However, a device for performing the transfer function calculating operation S10 is not limited to this embodiment. When characteristics of the noise measuring line 31 are not ignored, the characteristics of the noise measuring line 31 may be included in the transfer function H(f).

The transfer function calculating operation S10 is performed by a circuit simulator mounted in the computer 40. An example of the circuit simulator is a simulation program with integrated circuit emphasis (SPICE) strictly considering physical characteristics. The method of calculating the transfer function H(f) is not limited to simulation. For example, the transfer function H(f) may be acquired by bringing probes into contact with an exposed portion formed by exposing an output portion of the integrated circuit 1 and the noise measuring point P1. That is, the transfer function H(f) may be calculated by measurement. The transfer function H(f) may be calculated in combination of simulation and measurement.

The computer 40 simulates a voltage Vₒᵤₜ(f) at the noise measuring point P1 with respect to a current Iᵢₙ(f) at the observation point P0 in the integrated circuit 1. The computer 40 performs frequency analysis of the transfer function H(f) obtained by dividing the voltage Vₒᵤₜ(f) at the noise measuring point P1 by the current Iᵢₙ(f) at the observation point P0 and generates the transfer function H(f) with the frequency f as a variable as represented by Expression 1.

$$H ( f ) = \frac{{V}_{out} ( f )}{{I}_{in} ( f )} \qquad ( Expression 1 )$$

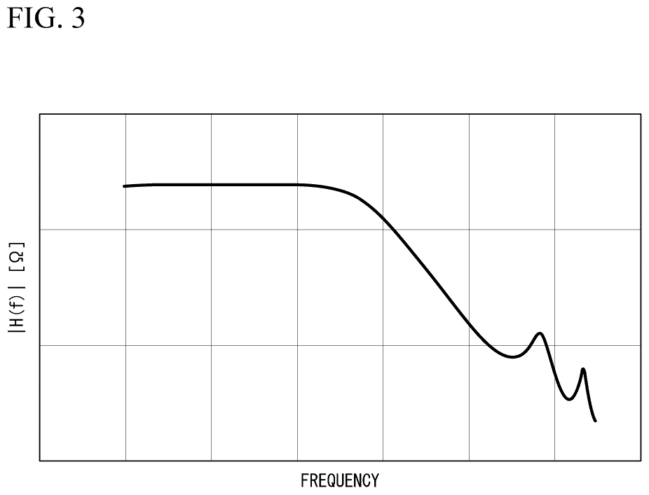

FIG. 3 is a diagram illustrating an example of the transfer function H(f) calculated in the transfer function calculating operation S10. In FIG. 3, the horizontal axis represents the frequency, and the vertical axis represents the absolute value of the transfer function H(f).

As illustrated in FIG. 2, the noise level waveform acquiring operation S20 is an operation that can be performed in parallel with the transfer function calculating operation S10. Accordingly, either the transfer function calculating operation S10 or the noise level waveform acquiring operation S20 may be performed earlier or both may be performed simultaneously.

The noise level waveform acquiring operation S20 includes a measurement operation S21, a conversion operation S22, a correlation value calculating operation S23, and a filtering operation S24. The measurement operation S21, the conversion operation S22, the correlation value calculating operation S23, and the filtering operation S24 are performed in this order.

In the measurement operation S21, the integrated circuit 1 is caused to output a trigger signal T and noise N is measured using the oscilloscope 30. As illustrated in FIG. 1, a trigger signal voltage Vt output from the integrated circuit 1 is output to the output pattern 2a of the substrate 2 and is input to the trigger signal measuring channel Ch2 of the oscilloscope 30 via the output measuring line 32. Certain noise Nis generated in the electric circuit 3 regardless of whether a trigger signal Tis output, and the noise N is input from a noise measuring point P of the substrate to the noise measuring channel Ch1 of the oscilloscope 30 via the noise measuring line 31. The oscilloscope 30 measures the trigger signal voltage Vt and a noise voltage at time intervals before and after the trigger signal T is output.

In this specification, “measurement at time intervals” means that measurement and recording of a measured value are performed at intervals of a predetermined sampling time. The oscilloscope 30 measures the trigger signal voltage Vt and the noise voltage at time intervals, records changes over time of the measured values, and draws a waveform with time set as the horizontal axis and voltage set as the vertical axis.

In this embodiment, the oscilloscope 30 measures voltages of the trigger signal T and the noise N, but the oscilloscope 30 may measure current values of the trigger signal T and the noise N. That is, in the measurement operation S21, a parameter to be measured may be a voltage or a current value as long as the trigger signal T and the noise N are measured.

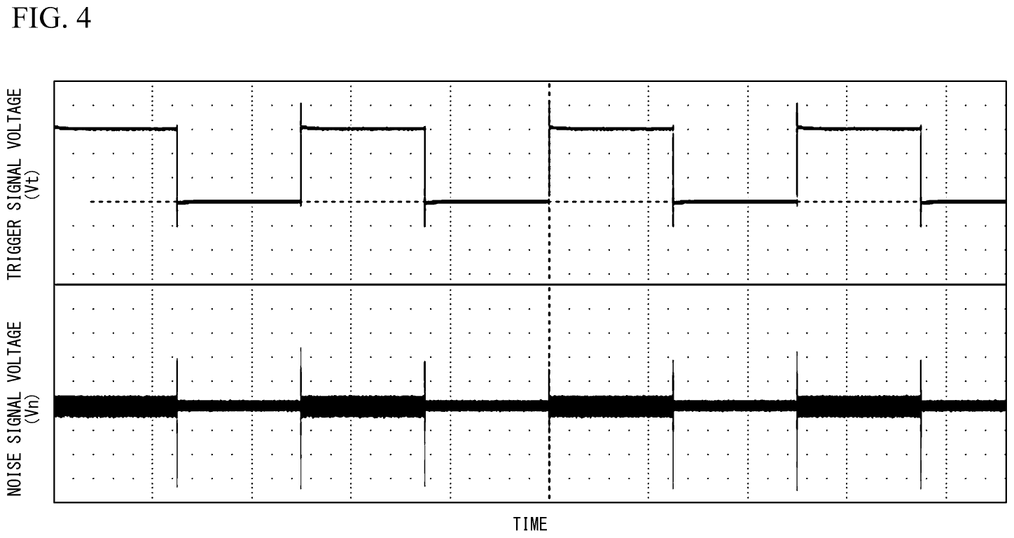

FIG. 4 is a graph illustrating changes over time of the trigger signal voltage Vt and the noise voltage Vn which are measured by the oscilloscope 30. In FIG. 4, the horizontal axis represents the time, and the vertical axis represents the voltage. In the example illustrated in FIG. 4, the integrated circuit 1 operates in a pattern in which output and stop of the trigger signal T are repeated at predetermined time intervals.

In the example illustrated in FIG. 4, the noise voltage Vn measured by the oscilloscope 30 increases at a timing at which the trigger signal Tis output. That is, it is ascertained that the noise N is output with outputting of the trigger signal T. However, floor noise such as noise based on a measuring instrument is also superimposed on the output of the noise N in the output of the trigger signal T. Accordingly, it is difficult to determine what component of the output noise voltage Vn is based on the output of the trigger signal T with reference to FIG. 4.

The conversion operation S22 is a operation of converting a waveform of the noise voltage Vn measured by the oscilloscope 30 and calculating a change of the noise over time voltage Vn for each frequency. In the following description, the change of the noise over time voltage Vn for each frequency is referred to as a “noise level waveform.” That is, the conversion operation is an operation of generating a noise level waveform indicating the change of the noise over time voltage Vn for each frequency on the basis of the measured value at the noise measuring point P1. The conversion operation S22 is performed by the computer 40 connected to the oscilloscope 30.

In the conversion operation S22 according to this embodiment, a noise level waveform for each frequency is generated by performing short-time Fourier transform of the waveform of the noise voltage Vn. That is, a result of short-time Fourier transform of the noise voltage Vn(t) is a noise level waveform Vn(f, t). By performing the short-time Fourier transform on the noise voltage Vn, it is possible to extract a period in which noise is great while leaving time information and to analyze the noise frequency. Particularly, by employing the short-time Fourier transform as the conversion method, it is possible to analyze a frequency spectrum with a constant resolution.

In this embodiment, it is preferable that the short-time Fourier transform be performed at time intervals equal to or less than 1 ms. By setting the resolution of the short-time Fourier transform to 1 ms or less, it is possible to analyze a frequency spectrum with a sufficient resolution.

In the conversion operation S22, wavelet transform may be performed instead of the short-time Fourier transform. When the wavelet transform is performed, the time intervals are not constant, and thus there is concern about a decrease in resolution with respect to the time axis in a desired section.

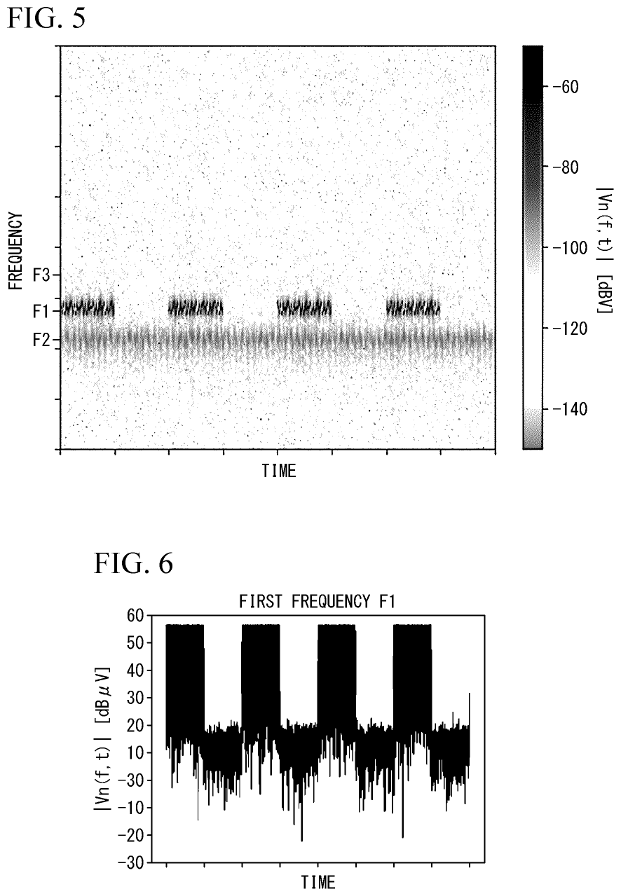

FIG. 5 is a graph illustrating a noise level waveform generated in the conversion operation S22. In FIG. 5, the horizontal axis represents the time, the vertical axis represents the frequency, and a color gradation represents the absolute value of a noise level (voltage).

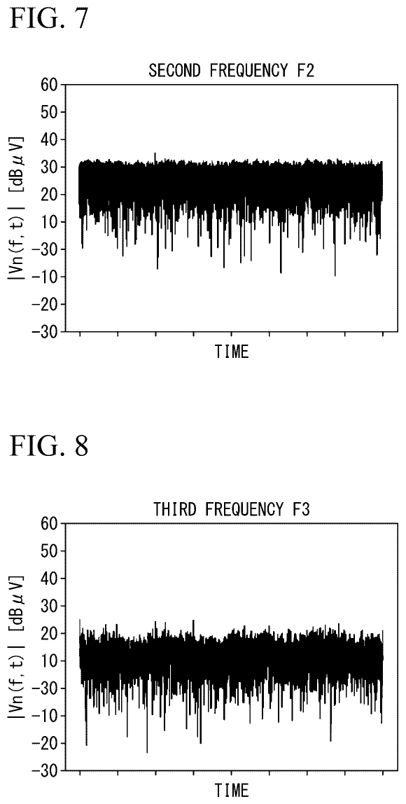

FIG. 6 is a graph illustrating a noise level waveform at a first frequency F1 in FIG. 5. FIG. 7 is a graph illustrating a noise level waveform at a second frequency F2 in FIG. 5. FIG. 8 is a graph illustrating a noise level waveform at a third frequency F3 in FIG. 5. In FIGS. 6 to 8, the horizontal axis represents the time, and the vertical axis represents the absolute value of Vn(f, t) which is the short-time Fourier transform.

As illustrated in FIGS. 5 and 6, the first frequency F1 is a frequency of the noise N that is output with outputting of the trigger signal T. As illustrated in FIGS. 5 and 7, the second frequency F2 is a frequency of the noise N that is output regardless of outputting of the trigger signal T. As illustrated in FIGS. 5 and 8, the third frequency F3 is considered to be floor noise.

The correlation value calculating operation S23 is an operation of calculating a correlation value Cn(f) indicating a correlation between the noise level waveform Vn(f, t) for each frequency and the change of the trigger signal over time voltage Vt(t). The correlation value calculating operation S23 is performed by the computer 40.

Expression 2 described below represents a correlation function C (f) between the noise level waveform Vn(f, t) and the trigger signal voltage Vt. Expression 3 described below represents a correlation value Cn(f) acquired by making Expression 2 dimensionless.

$$C ( f ) = max ( {\sum }_{k} {V}_{t} ( k + t ) * {V}_{n} ( f , k ) ) \qquad ( Expression 2 )$$

$${C}_{n} ( f ) = \frac{C ( f )}{max ( C ( f ) )} \qquad ( Expression 3 )$$

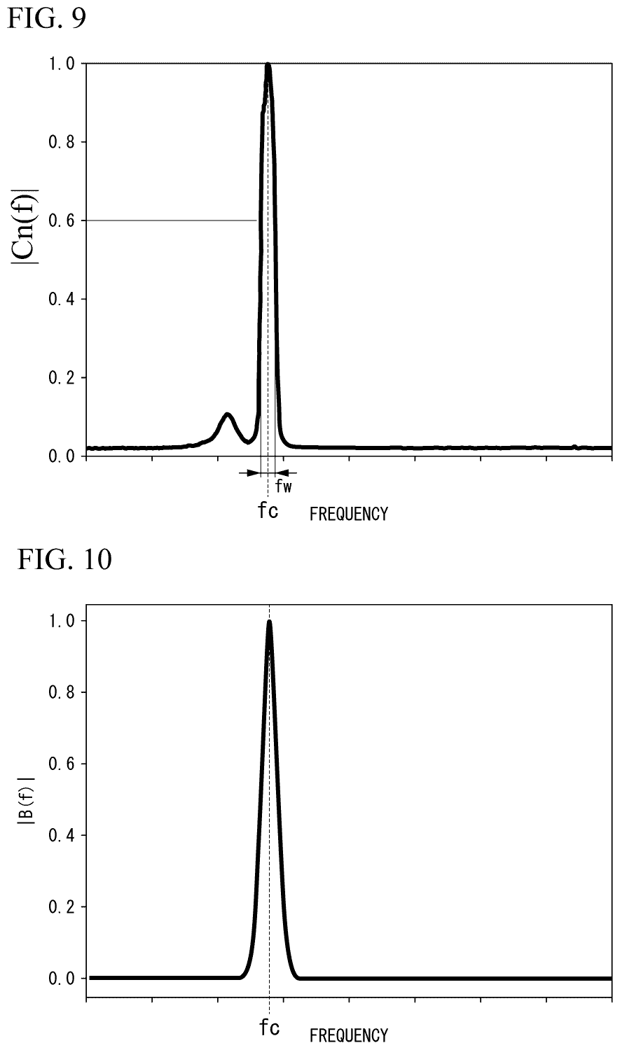

FIG. 9 is a graph illustrating a correlation value Cn(f) between the noise level waveform and the trigger signal T according to this embodiment acquired in the correlation value calculating operation S23. In FIG. 9, the horizontal axis represents the frequency, and the vertical axis represents the absolute value of the correlation value Cn(f). In FIG. 9, the correlation increases as the absolute value of the correlation value Cn(f) becomes close to 1, and the correlation decreases as the absolute value of the correlation value Cn(f) becomes close to 0.

The filtering operation S24 is an operation of extracting a noise level waveform of a frequency with a high correlation on the basis of the correlation value Cn(f) calculated in the correlation value calculating operation S23. The filtering operation S24 is performed by the computer 40.

As illustrated in FIG. 9, in this embodiment, there is considered to be a correlation between the noise level waveform and the trigger signal T at a frequency at which the absolute value of the correlation value Cn(f) is equal to or greater than 0.6. That is, in this embodiment, a threshold value for determining whether there is a correlation is set to 0.6. The threshold value is appropriately set in advance in consideration of accuracy of a noise model, a balance such as a calculation time, and the like.

As illustrated in FIG. 9, a frequency range in which the absolute value of the correlation value Cn(f) is equal to or greater than 0.6 is defined as a frequency width fw. A frequency at the center of the frequency width fw is referred to as a center frequency fc. In this embodiment, the center frequency fc has a value in the vicinity of the first frequency F1 in FIG. 5.

In the filtering operation S24 according to this embodiment, noise N of a frequency with a low correlation value Cn (not greater than the threshold value) is removed using a band-pass filter B(f). First, a bandwidth Bw is calculated from the frequency width fw using Expression 4 described below. By substituting the calculated bandwidth Bw and the center frequency fc into Expression 5, the band-pass filter B(f) is generated. FIG. 10 illustrates a characteristic diagram of the band-pass filter B(f) according to this embodiment.

$${B}_{w} = {f}_{w} * \sqrt{\frac{π}{2 * ln 2}} \qquad ( Expression 4 )$$

$$B ( f ) = {e}^{- π {( \frac{f - {f}_{c}}{{B}_{w}} )}^{2}} \qquad ( Expression 5 )$$

As represented by Expression 6 described below, a filtering operation can be performed on the noise level waveform by multiplying the generated band-pass filter B(f) and the noise level waveform Vn(f, t). In the following description, a filtered noise level waveform is referred to as an extracted noise level waveform Vnn(f, t). That is, in the filtering operation S24, the extracted noise level waveform Vnn(f, t) is calculated.

$${V}_{nn} ( f , t ) = B ( f ) * {V}_{n} ( f , t ) \qquad ( Expression 6 )$$

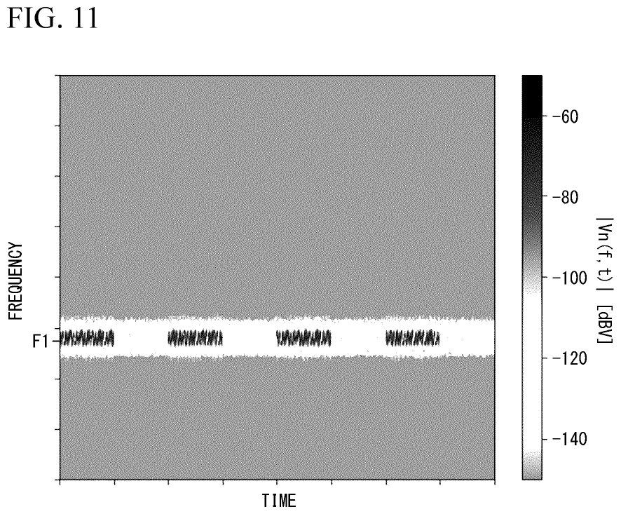

FIG. 11 is a diagram illustrating an extracted noise level waveform Vnn(f, t) according to this embodiment. In FIG. 11, the horizontal axis represents the time, the vertical axis represents the frequency, and a color gradation represents the absolute value of a noise level (voltage). FIG. 11 is different from FIG. 5 in that noise N other than in the vicinity of the first frequency F1 with a high correlation with the trigger signal Tis removed.

By performing the measurement operation S21, the conversion operation S22, the correlation value calculating operation S23, and the filtering operation S24, the noise level waveform acquiring operation S20 is completed. In this way, the noise level waveform acquiring operation S20 is an operation of acquiring a noise level waveform of a frequency with a high correlation with the trigger signal T (that is, an extracted noise level waveform Vnn(f, t)) from the measurement results of the noise N when the integrated circuit 1 is caused to output the trigger signal T.

The noise model generating operation S30 is an operation of generating a noise model of the integrated circuit 1 on the basis of the transfer function H(f) calculated in the transfer function calculating operation S10 and the noise level waveform Vn(f, t) acquired in the noise level waveform acquiring operation S20. In the noise model generating operation S30, a noise current I(f) can be calculated as a noise model, for example, on the basis of Expression 7 described below. The noise model generating operation S30 is performed by the computer 40.

$$I ( f ) = \frac{Vnn ( f )}{H ( f )} \qquad ( Expression 7 )$$

The noise model I(f) acquired in the noise model generating operation S30 according to this embodiment can be used to evaluate noise of the integrated circuit 1.

The configuration described above in the embodiment is only an example and may be appropriately combined with another configuration. For example, in this embodiment, the trigger signal T and the noise N are measured using the oscilloscope 30 in the measurement operation S21. However, a measuring instrument used in the measurement operation S21 is not limited to the oscilloscope 30 as long as it can measure changes of the trigger signal T and the noise N over time.

In a noise model generating method according to the related art, measured values of noise serving as a basis of analysis do not reflect a change over time of noise with respect to inputting of a trigger signal T. Accordingly, the generated noise model is affected by noise which is generated regardless of the trigger signal T and thus accuracy of the noise model decreases. There is a problem in that a correlation between a type of the trigger signal T and the generated noise cannot be accurately ascertained and a noise model has difficulty taking basic measures for curbing noise even when the noise model is generated.

The noise model generating method according to this embodiment is a noise model generating method for the integrated circuit 1. As illustrated in FIG. 2, the noise model generating method includes the transfer function calculating operation S10, the noise level waveform acquiring operation S20, and the noise model generating operation S30. The transfer function calculating operation S10 is an operation of constituting the electric circuit 3 including the integrated circuit 1 and calculating a transfer function H(f) from the inside of the integrated circuit 1 to the noise measuring point P1 on the electric circuit 3. The noise level waveform acquiring operation S20 is a operation of acquiring a noise level waveform of a frequency with a high correlation with a trigger signal T (an extracted noise level waveform Vnn(f, t)) from measurement results of noise N when the integrated circuit 1 is caused to output the trigger signal T. The noise model generating operation S30 is an operation of generating a noise mode I(f) of the integrated circuit 1 on the basis of the transfer function H(f) calculated in the transfer function calculating operation S10 and the noise level waveform Vn(f, t) acquired in the noise level waveform acquiring operation S20. The noise level waveform acquiring operation S20 includes the measurement operation S21, the conversion operation S22, the correlation value calculating operation S23, and the filtering operation S24. The measurement operation S21 is an operation of causing the integrated circuit 1 to output a trigger signal T and measuring the trigger signal T and noise N at the noise measuring point P1 at time intervals. The conversion operation S22 is an operation of generating a noise level waveform Vn(f, t) indicating a change of the noise over time N for each frequency on the basis of the measured value at the noise measuring point P1. The correlation value calculating operation S23 is an operation of calculating a correlation value Cn(f) indicating a correlation between the noise level waveform Vn(f, t) for each frequency and the change of the trigger signal over time T. The filtering operation S24 is an operation of extracting a noise level waveform of a frequency with a high correlation(an extracted noise level waveform Vnn(f, t)) from the correlation value Cn(f).

With this configuration, only the noise N output with respect to the trigger signal Tis extracted as the extracted noise level waveform Vnn(f, t) in the noise level waveform acquiring operation S20, and the noise model I(f) is generated in the noise model generating operation S30. Accordingly, it is possible to generate the noise model I(f) while curbing an influence of the noise N not associated with the trigger signal T and to enhance accuracy of the generated noise model I(f).

With this configuration, the integrated circuit 1 having various operation modes can be caused to output various trigger signals T corresponding to the operation modes, and the noise model I(f) for each of the operation modes can also be separately calculated. In this case, by analyzing the noise models I(f) of the operation modes, a circuit serving as a noise source in the integrated circuit 1 operating in the operation modes can be identified and corrected, which can be usefully used to decrease generation of noise.

In the noise model generating method according to the embodiment, the conversion operation S22 is an operation of performing short-time Fourier transform of a waveform of noise at the noise measuring point P1.

With this configuration, it is possible to extract a frequency spectrum of noise while leaving time information. Accordingly, in the correlation value calculating operation S23, it is possible to easily calculate a correlation with the trigger signal T (that is, a correlation value Cn(f)) through comparison with time information of the trigger signal T. By preforming the conversion operation using the short-time Fourier transform, it is possible to keep the temporal resolution constant and to perform analysis with a desired resolution.

In the noise model generating method according to the embodiment, the filtering operation S24 is an operation of extracting the noise level waveform Vn(f, t) of a frequency of which the correlation value Cn(f) is greater than a threshold value.

With this configuration, in the filtering operation S24, it is possible to easily extract the noise level waveform Vn(f, t) with respect to the threshold value.

In the noise model generating method according to the embodiment, the measurement operation S21 is an operation of measuring the noise in the strip line 50 connected to the substrate 2 on which the integrated circuit 1 is mounted.

With this configuration, it is possible to directly measure noise N radiated from the integrated circuit 1 using the strip line 50 and to enhance measurement accuracy of noise N at the noise measuring point P1.

The noise model generating device 100 according to the embodiment performs the noise model generating method.

With this configuration, it is possible to generate an accurate noise model I(f) of the integrated circuit 1 and to usefully use the noise model for circuit design or correction of the integrated circuit 1.

According to at least one embodiment described above, since only the noise N output with respect to the trigger signal T is extracted and the noise model I(f) is generated, it is possible to provide a noise level generating method that can enhance accuracy of the generated noise model I(f).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A noise model generating method of generating a noise model of an integrated circuit, the noise model generating method comprising:
calculating a transfer function from inside of an integrated circuit of an electric circuit to a measurement point in the electric circuit;
acquiring a noise level waveform of a frequency with a high correlation with a trigger signal from measurement results of noise when the integrated circuit is caused to output the trigger signal; and
generating the noise model of the integrated circuit on the basis of the transfer function calculated and the noise level waveform acquired,
wherein acquiring the noise level waveform further comprises:
causing the integrated circuit to output a trigger signal;
measuring the trigger signal and noise at the measurement point at time intervals to obtain measured values at the measurement point and at the time intervals;
performing a conversion operation to generate, for each frequency, the noise level waveform indicating a change of the noise over time on the basis of the measured values at the measurement point;
calculating, for each frequency, a correlation value indicating a correlation between the noise level waveform and a change of the trigger signal over time; and
performing a filtering operation to extract the noise level waveform of a frequency with a high correlation from the correlation value.

2. The noise model generating method according to claim 1, wherein performing the conversion operation comprises performing short-time Fourier transform of a waveform of the noise at the measurement point.

3. The noise model generating method according to claim 1, wherein performing the filtering operation comprises extracting the noise level waveform of a frequency of which the correlation value is greater than a threshold value.

4. The noise model generating method according to claim 1, wherein measuring the trigger signal and noise at the measurement point comprises measuring the noise at a strip line connected to a substrate on which the integrated circuit is mounted.

5. A noise model generating system comprises:
a computer configured to perform a noise model generating method that comprises:
calculating a transfer function from inside of an integrated circuit of an electric circuit to a measurement point in the electric circuit;
acquiring a noise level waveform of a frequency with a high correlation with a trigger signal from measurement results of noise when the integrated circuit is caused to output the trigger signal; and
generating the noise model of the integrated circuit on the basis of the transfer function calculated and the noise level waveform acquired,
wherein acquiring the noise level waveform further comprises:
causing the integrated circuit to output a trigger signal;
measuring the trigger signal and noise at the measurement point at time intervals to obtain measured values at the measurement point and at the time intervals;
performing a conversion operation to generate, for each frequency, the noise level waveform indicating a change of the noise over time on the basis of the measured values at the measurement point;
calculating, for each frequency, a correlation value indicating a correlation between the noise level waveform and a change of the trigger signal over time; and
performing a filtering operation to extract the noise level waveform of a frequency with a high correlation from the correlation value.

6. The noise model generating system according to claim 5, wherein performing the conversion operation comprises performing short-time Fourier transform of a waveform of the noise at the measurement point.

7. The noise model generating system according to claim 5, wherein performing the filtering operation comprises extracting the noise level waveform of a frequency of which the correlation value is greater than a threshold value.

8. The noise model generating system according to claim 5, wherein measuring the trigger signal and noise at the measurement point comprises measuring the noise at a strip line connected to a substrate on which the integrated circuit is mounted.
